(19) United States
(12) Patent Application Publication
(10) Pub. No.: US 2012/0273839 A1
(43) Pub. Date: Nov. 1, 2012

(54) SEMICONDUCTOR WAFER, METHOD FOR PRODUCING SEMICONDUCTOR WAFER, AND METHOD FOR PRODUCING PHOTO-ELECTRIC CONVERSION DEVICE

(75) Inventors: Masahiko HATA, Tsuchiura-shi (JP); Hisashi YAMADA, Phoenix, AZ (US); Tomoyuki TAKADA, Tsukuba-shi (JP)

(73) Assignee: SUMITOMO CHEMICAL COMPANY, LIMITED, Tokyo (JP)

(21) Appl. No.: 13/531,192

(22) Filed: Jun. 22, 2012

Related U.S. Application Data
(63) Continuation-in-part of application No. PCT/JP2010/007467, filed on Dec. 24, 2010.

(30) Foreign Application Priority Data
Dec. 25, 2009 (JP) 2009-296104

(51) Int. Cl. H01L 29/267; H01L 31/0336; H01L 21/20

(52) U.S. Cl. 257/190; 438/478; 438/94; 257/E29.081; 257/E21.09; 257/E31.005

(57) ABSTRACT

A semiconductor wafer includes a base wafer, a sacrificial layer that is lattice-matched or pseudo lattice-matched to the base wafer, a first crystal layer that is formed on the sacrificial layer and made of an epitaxial crystal of SiₓGe₁₋ₓ, (0≦x<1), and a second crystal layer that is formed on the first crystal layer and made of an epitaxial crystal of a group 3-5 compound semiconductor having a larger band gap than the first crystal layer. The base wafer is, for example, made of single-crystal GaAs. The sacrificial layer is, for example, made of an epitaxial crystal of InₘAlₙGa₁₋ₘ₋ₙAs (0≦m<1, 0<n≦1, 0<n+m≦1).

### CROSS REFERENCE TO RELATED APPLICATION

The contents of the following Japanese patent application are incorporated herein by reference:

No. 2009-296104 filed on Dec. 25, 2009.

The contents of the following International patent application are incorporated herein by reference: No. PCT/JP2010/007467 filed on Dec. 24, 2010.

### BACKGROUND

1. Technical Field

The present invention relates to a semiconductor wafer, a method for producing a semiconductor wafer, and a method for producing a photo-electric conversion device.

2. Related Art

Non-Patent Document 1 discloses a compound semiconductor photovoltaic cell. This document discloses an InGaP/GaAs/InGaAs (1 eV) cell as a triple-junction photovoltaic cell having an optimal band gap combination.

Non-Patent Document 1: Report of Achievements from July 2006 to June 2007, New Energy Technology Development, Photovoltaic System Future Technology Research Development, Research and Development of Ultrahigh Efficiency Multi-Junction Photovoltaic Cell, New Energy and Industrial Technology Development Organization, March 2008

In the field of multi-junction photovoltaic cells, it is aimed to improve the photo-electric conversion efficiency by optimizing the differences in hand gap between the materials forming the respective layers of the multi-junction photovoltaic cells. Higher photo-electric conversion efficiency requires the use of materials having a superior light absorption coefficient at the longer wavelengths, and such materials are preferably produced easily. Furthermore, the individual layers of the multi-junction photovoltaic cells are preferably made of good-quality crystals.

### SUMMARY

For a solution to the above-mentioned problems, according to the first aspect related to the present invention, provided is one exemplary semiconductor wafer includes a base wafer, a sacrificial layer that is lattice-matched or pseudo lattice-matched to the base wafer, a first crystal layer that is formed on the sacrificial layer and made of an epitaxial crystal of SiₓGe₁₋ₓ (0≦x<1), and a second crystal layer that is formed on the first crystal layer and made of an epitaxial crystal of a group 3-5 compound semiconductor having a larger band gap than the first crystal layer. For example, the base wafer is made of single-crystal GaAs.

For example, the sacrificial layer is made of an epitaxial crystal of InₘAlₙGa₁₋ₘ₋ₙAs (0≦m<0.2, 0.8≦n≦1, 0.8<n+m≦1) or In_{0.5}Al_{0.5}P. The sacrificial layer is preferably made of AlₙGa1-nAs (0.8≦n≦1) or In_{0.18}Al_{0.52}P.

The semiconductor wafer may further include an intermediate crystal layer that is formed between the first crystal layer and the second crystal layer and made of an epitaxial crystal of a group 3-5 compound semiconductor. For example, the intermediate crystal layer has a larger band gap than the first crystal layer and a smaller band gap than the second crystal layer. For example, the intermediate crystal layer is made of In_{y}Ga_{1-y}As_{z}P_{1-z} (0≦y<1, 0<z≦1), and the second crystal layer is made of Al_{w}InₜGa_{1-w-t}As_{z′}P_{1-z′}(0≦w≦1, 0≦t≦1, 0≦w+t≦1, 0≦z≦1), for example.

The semiconductor wafer may include, on the sacrificial layer, a first back surface field layer, the first crystal layer, a first window layer, a first tunnel junction layer, a second back surface field layer, the intermediate crystal layer, a second window layer, a second tunnel junction layer, a third back surface field layer, the second crystal layer, and a third window layer arranged in the stated order, and the first back surface field layer, the second back surface field layer, the third back surface field layer, the first window layer, the second window layer and the third window layer may have a larger hand gap than any layer selected from among the first crystal layer, the intermediate crystal layer and the second crystal layer.

According to the second aspect related to the present invention, provided is one exemplary method for producing a semiconductor wafer. The production method includes forming, on a base wafer, a sacrificial layer that is lattice-matched or pseudo lattice-matched to the base wafer, epitaxially growing, on the sacrificial layer, a first crystal layer made of SiₓGe₁₋ₓ (0≦x<1), epitaxially growing, on the first crystal layer, an intermediate crystal layer made of a group 3-5 compound semiconductor, and epitaxially growing, on the intermediate crystal layer, a second crystal layer made of a group 3-5 compound semiconductor that has a larger band gap than the first crystal layer.

For example, the base wafer is made of single-crystal GaAs. During the epitaxial growth of the sacrificial layer, an epitaxial crystal layer made of InₘAlₙGa₁₋ₘ₋ₙAs (0≦m<0.2, 0.8≦n<1, 0.8<n+m≦1) is epitaxially grown.

The intermediate crystal layer has a larger band gap than the first crystal layer and a smaller band gap than the second crystal layer. Furthermore, a tunnel junction layer is preferably formed between the first crystal layer and the intermediate crystal layer and another tunnel junction layer is formed between the intermediate crystal layer and the second crystal layer. The intermediate crystal layer is, for example, made of In_{y}Ga_{1-y}As_{z}P_{1-z} (0≦y<1, 0<z≦1), and the second crystal layer is, for example, made of Al_{w}InₜGa_{1-w-t}As_{z′}P_{1-z′} (0≦w≦1, 0≦t≦1, 0≦w+t≦1, 0≦z≦1).

The method for producing a semiconductor wafer may include forming, on the sacrificial layer, a first back surface field layer, forming, on the first back surface field layer, the first crystal layer, forming, on the first crystal layer, a first window layer, forming, on the first window layer, a first tunnel junction layer, forming, on the first tunnel junction layer, a second back surface field layer, forming, on the second back surface field layer, the intermediate crystal layer, forming, on the intermediate crystal layer, a second window layer, forming, on the second window layer, a second tunnel junction layer, forming, on the second tunnel junction layer, a third back surface field layer, forming, on the third back surface field layer, the second crystal layer, and forming, on the second crystal layer, a third window layer. Here, the first back surface field layer, the second back surface field layer, the third back surface field layer, the first window layer, the second window layer and the third window layer may have a larger band gap than any layer selected from among the first crystal layer, the intermediate crystal layer and the second crystal layer.

According to the method for producing a semiconductor wafer, the epitaxial growth of the sacrificial layer may he performed in a different atmosphere than the epitaxial growth of the first crystal layer, and the epitaxial growth of the first crystal layer may be performed in a different atmosphere than the epitaxial growth of the intermediate crystal layer. For example, the method for producing a semiconductor wafer further includes, between the epitaxial growth of the sacrificial layer and the epitaxial growth of the first crystal layer, and between the epitaxial growth of the first crystal layer and the epitaxial growth of the intermediate crystal layer, replacing the atmosphere in a reaction chamber to perform the respective epitaxial growths with one or more gases selected from hydrogen, nitrogen and argon, or reducing the pressure in the reaction chamber.

According to the method for producing a semiconductor wafer, the epitaxial growth of the first crystal layer may he performed in a different reaction chamber than the epitaxial growth of the intermediate crystal layer and the epitaxial growth of the second crystal layer.

According to the third aspect related to the present invention, provided is one exemplary method for producing a semiconductor wafer. The production method includes forming, on a base wafer, a sacrificial layer that is lattice-matched or pseudo lattice-matched to the base wafer, epitaxially growing, on the sacrificial layer, a second crystal layer made of a group 3-5 compound semiconductor that has a larger band gap than the sacrificial layer, epitaxially growing, on the second crystal layer, an intermediate crystal layer made of a group 3-5 compound semiconductor, and epitaxially growing, on the intermediate crystal layer, a first crystal layer made of SiₓGe₁₋ₓ (0≦x<1).

According to the fourth aspect related to the present invention, provided is one exemplary method for producing a photo-electric conversion device. The production method includes providing the semiconductor wafer according to the first aspect, attaching a first support onto the second crystal layer, and removing the sacrificial layer to separate the first crystal layer from the base wafer. The production method may further include attaching a second support made of any material selected from among a metal, a plastic, and a ceramic onto a surface of the first crystal layer that is exposed by the separation from the base wafer, and removing the first support. The first support may be transparent, and the production method may further include attaching a second support that is made of any material selected from among a metal, a plastic, and a ceramic onto a surface of the first crystal layer that is exposed by the separation from the base wafer. The separated base wafer may be reused for producing the semiconductor wafer according to the first aspect.

According to the fifth aspect related to the present invention, provided is one exemplary method for producing a photo-electric conversion device. The production method includes providing the semiconductor wafer as set forth in claim 1, and forming a plurality of electrodes that are to be electrically coupled to the base wafer and the second crystal layer. Here, the base wafer is made of a semiconductor having a p-type or an n-type conductivity.

### BRIEF DESCRIPTION OF THE DRAWINGS

FIG. 1 illustrates the cross-section of a photo-electric conversion device 100.

FIG. 2 illustrates the cross-section of a photo-electric conversion device 200.

FIG. 3 illustrates the cross-section of a photo-electric conversion device 300.

FIG. 4 illustrates the cross-section of a photo-electric conversion device 400.

FIG. 5A illustrates the cross-section of a semiconductor wafer 500.

FIG. 5B illustrates the cross-section of the semiconductor wafer 500.

FIG. 6 illustrates the cross-section of the photo-electric conversion device 200 observed during its production process.

FIG. 7 illustrates the cross-section of the photo-electric conversion device 200 observed during its production process.

FIG. 8 illustrates the cross-section of a semiconductor wafer 600.

FIG. 9 illustrates the cross-section of the photo-electric conversion device 200 observed during its production process.

### DESCRIPTION OF EXEMPLARY EMBODIMENTS

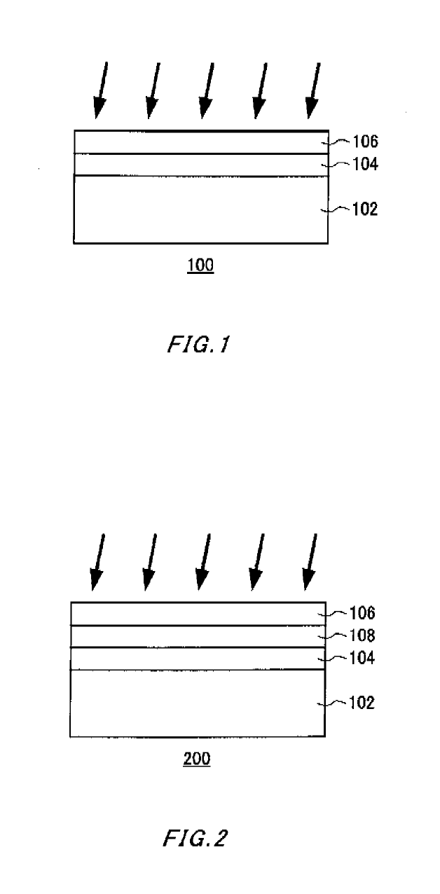

The following describes the present invention with reference to embodiments. FIG. 1 illustrates the cross-section of a photo-electric conversion device 100. The photo-electric conversion device 100 includes a support 102, a first crystal layer 104, and a second crystal layer 106. The second crystal layer 106 and the first crystal layer 104 are arranged in the stated order in the incoming light direction. The first crystal layer 104 is a bottom layer formed in the most distant region from the incoming light side. The second crystal layer 106 is a top layer that is designed to receive light first. The photo-electric conversion device 100 may include additional layers between the second crystal layer 106 and the first crystal layer 104.

The first crystal layer 104 is configured to absorb light to generate electromotive force. The first crystal layer 104 is an epitaxial crystal layer of SiₓGe₁₋ₓ (0≦x<1), preferably an epitaxial crystal layer of SiₓGe₁₋ₓ (0<x<0.2). The first crystal layer 104 is preferably lattice-matched or pseudo lattice-matched to single-crystal gallium arsenide (GaAs). The first crystal layer 104 is preferably constituted by stacking a p-type SiₓGe₁₋ₓ epitaxial crystal layer and an n-type SiₓGe₁₋ₓ epitaxial crystal layer on one another. Here, the second crystal layer 106 and other epitaxial crystal layers disclosed herein are preferably lattice-matched or pseudo lattice-matched to single-crystal gallium arsenide.

The second crystal layer 106 is configured to absorb light to generate electromotive force. The second crystal layer 106 is an epitaxial crystal layer made of a group 3-5 compound semiconductor having a larger band gap than the first crystal layer 104. The second crystal layer 106 is, for example, made of Al_{w}InₜGa_{1-w-t}As_{z′}P_{1-z′} (0≦w≦1, 0≦t≦1, 0≦w+t≦1, 0≦z′≦1). The second crystal layer 106 is preferably made of In_{0.5}Ga_{0.5}P, more preferably made of In_{0.48}Ga_{0.52}P. The second crystal layer 106 is preferably constituted by stacking a p-type Al_{w}InₜGa_{1-w-t}As_{z′}P_{1-z′} epitaxial crystal layer and an n-type As_{w}InₜGa_{1-w-t}As_{z′}P_{1-z′} epitaxial crystal layer on one another.

In the photo-electric conversion device 100, the bottom first crystal layer 104 is an epitaxial crystal layer of SiₓGe₁₋ₓ (0≦x<1) and thus has a smaller hand gap than the top second crystal layer 106. Thus, the bottom first crystal layer 104 absorbs the light in the long wavelength region that cannot be absorbed by the second crystal layer 106. In this manner, the conversion efficiency of the photo-electric conversion device 100 can be improved. Since SiₓGe₁₋ₓ (0≦x<1) can be lattice-matched or pseudo lattice-matched to a group 3-5 compound semiconductor, the crystallinity of the second crystal layer 106, which is made of a group 3-5 compound semiconductor, is improved. Accordingly, the conversion efficiency of the photo-electric conversion device 100 is improved.

The first crystal layer 104 and the second crystal layer 106 are supported by the support 102. The support 102 is made of one or more materials selected from the group consisting of metals, plastics, and ceramics. The metals include aluminum, copper, stainless steel. The plastics include polyimide, liquid crystal polymer, cycloolefin polymer, polycarbonate, acrylic resin, and polyolefin. The ceramics include polycrystalline alumina sintered body, polycrystalline aluminum nitride sintered body, polycrystalline silicon carbide sintered body, and polycrystalline silica. The ceramics may not he crystalline but glass (amorphous) form.

FIG. 2 illustrates the cross-section of a photo-electric conversion device 200. The photo-electric conversion device 200 is obtained by adding an intermediate crystal layer 108 to the constituents of the photo-electric conversion device 100. The intermediate crystal layer 108 is formed between the first crystal layer 104 and the second crystal layer 106. The intermediate crystal layer 108 is configured to absorb light to generate electromotive force. The intermediate crystal layer 108 is an epitaxial crystal layer made of a group 3-5 compound semiconductor. The intermediate crystal layer 108 has a larger band gap than the first crystal layer 104 and a smaller band gap than the second crystal layer 106. The intermediate crystal layer 108 is made of, for example, In_{y}Ga_{1-y}As_{z}P_{1-z} (0≦y<1, 0<z≦1). The intermediate crystal layer 108 is preferably made of In_{y}Ga_{1-y}As (0≦y<0.1) and more preferably made of GaAs. The intermediate crystal layer 108 is preferably constituted by stacking a p-type In_{y}Ga_{1-y}As_{z}P_{1-z} epitaxial crystal layer and an n-type In_{y}Ga_{1-y}As_{z}P_{1-z} epitaxial crystal layer on one another.

Since the photo-electric conversion device 200 includes the intermediate crystal layer 108, the light that fails to be absorbed by the second crystal layer 106 is absorbed by the intermediate crystal layer 108. In addition, the light that fails to he absorbed by the intermediate crystal layer 108 is absorbed by the first crystal layer 104. In this manner, the photo-electric conversion device 200 achieves higher conversion efficiency than the photo-electric conversion device 100.

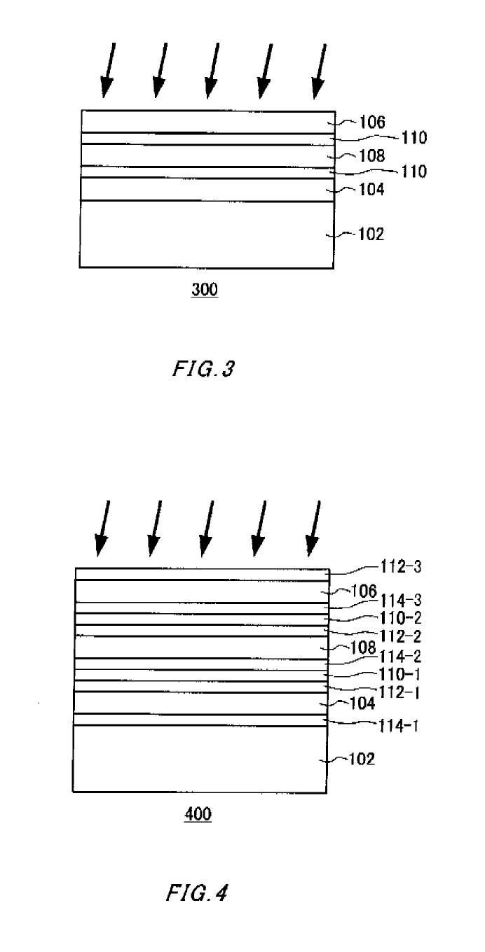

FIG. 3 illustrates the cross-section of a photo-electric conversion device 300. The photo-electric conversion device 300 is obtained by adding tunnel junction layers 110 to the constituents of the photo-electric conversion device 200. One of the tunnel junction layers 110 is positioned between the first crystal layer 104 and the intermediate crystal layer 108 and the other is positioned between the intermediate crystal layer 108 and the second crystal layer 106. The tunnel junction layers 110 provide superior connections at the junction interfaces between the first crystal layer 104, the intermediate crystal layer 108 and the second crystal layer 106.

As each of the tunnel junction layers 110, a p-n junction layer is used that is a combination of an N layer heavily doped with donor impurities and a P layer heavily doped with acceptor impurities. The N layer is an In_{y}Ga_{1-y}As_{z}P_{1-z} (0≦y<1, 0<z≦1) layer or an Al_{w}InₜGa_{1-w-t}As_{z′}P_{1-z′} (0≦w≦1, 0≦t≦1, 0≦w+t≦1, 0≦z′≦1) layer having donor impurities at the concentration of 5×10¹⁸/cm³ or higher. The P layer is an In_{y}Ga_{1-y}As_{z}P_{1-z} (0≦y<1, 0<z≦1) layer or an Al_{w}InₜGa_{1-w-t}As_{z′}P_{1-z′} (0≦w≦1, 0≦t≦1, 0≦w+t≦1, 0≦z′≦1) layer having acceptor impurities at the concentration of 5×10¹⁸/cm³ or higher.

The donor impurities are, for example, Si, S, Se, Te. The acceptor impurities are, for example, C, Be, Mg, Zn. The N layer and the P layer both preferably have a thickness of 50 nm or less, more preferably 30 nm or less. The N layer and the P layer are both preferably lattice-matched or pseudo lattice-matched to the first crystal layer 104, the intermediate crystal layer 108 or the second crystal layer 106.

As an alternative to the above-described p-n junction layer, the tunnel junction layer 110 in contact with the first crystal layer 104 may be a p-n junction layer that is obtained by combining an n-type SiₓGe₁₋ₓ (0≦x<1) layer heavily doped with donor impurities (5×10¹⁸/cm³ or higher) and a p-type SiₓGe₁₋ₓ (0≦x<1) layer heavily doped with acceptor impurities (5×10¹⁸/cm³ or higher). In this case, the donor impurities may be P, As or Sb. The acceptor impurities may be B, Al or Ga.

The n-type SiₓGe₁₋ₓ layer and the p-type SiₓGe₁₋ₓ layer both preferably have a thickness of 50 nm or less, more preferably 30 nm or less. The n-type layer and the p-type SiₓGe₁₋ₓ layer are both preferably lattice-matched or pseudo lattice-matched to the first crystal layer 104 or the intermediate crystal layer 108.

FIG. 4 illustrates the cross-section of a photo-electric conversion device 400. The photo-electric conversion device 400 is different from the photo-electric conversion device 300 in that a plurality of window layers 112 and a plurality of back surface field layers 114 are added. Specifically, the photo-electric conversion device 400 includes, on a support 102, a back surface field layer 114-1, a First crystal layer 104, a window layer 112-1, a tunnel junction layer 110-1, a back surface field layer 114-2, an intermediate crystal layer 108, a window layer 112-2, a tunnel junction layer 110-2, a back surface field layer 114-3, a second crystal layer 106, and a window layer 112-3 in the stated order.

The window layers 112 and the hack surface field layers 114 each have a larger band gap than any of the first crystal layer 104, the intermediate crystal layer 108 and the second crystal layer 106. Accordingly, the optical carriers generated in the first crystal layer 104, the intermediate crystal layer 108, and the second crystal layer 106 are prevented from transporting to outside the first crystal layer 104, the intermediate crystal layer 108, and the second crystal layer 106. Therefore, the window layers 112 and the back surface field layers 114 can efficiently extract the optical carriers.

The window layers 112 are each an In_{y}Ga_{1-y}As_{z}P_{1-z} (0≦y<1, 0<z≦1) layer or an Al_{w}InₜGa_{1-w-t}As_{z′}P_{1-z′} (0≦w≦1, 0≦t≦1, 0≦w+t≦1, 0≦z′≦1) layer. The window layer 112 in contact with the first crystal layer 104 can alternatively be a SiₓGe₁₋ₓ (0≦x<1) layer.

The back surface field layers 114 are each an In_{y}Ga_{1-y}As_{z}P_{1-z} (0≦y<1, 0<z≦1) layer or an Al_{w}InₜGa_{1-w-t}As_{z′}P_{1-z′} (0≦w≦1, 0≦t≦1, 0≦w+t≦1, 0≦z′≦1) layer. The back surface field layer 114 in contact with the first crystal layer 104 can alternatively be a SiₓGe₁₋ₓ (0≦x<1) layer.

The window layers 112 and the back surface field layers 114 both preferably have a thickness of 50 nm or less, more preferably 30 nm or less. The window layers 112 and the back surface field layers 114 are doped so as to have the same conductivity type as the first crystal layer 104, the intermediate crystal layer 108 or the second crystal layer 106 which is in contact with the window layers 112 and the back surface field layers 114. The window layers 112 and the back surface field layers 114 preferably have a doping concentration of 1×10¹⁸/cm³ or higher, more preferably 3×10¹⁸/cm³ or higher regardless of the conductivity type whether it is p or n.

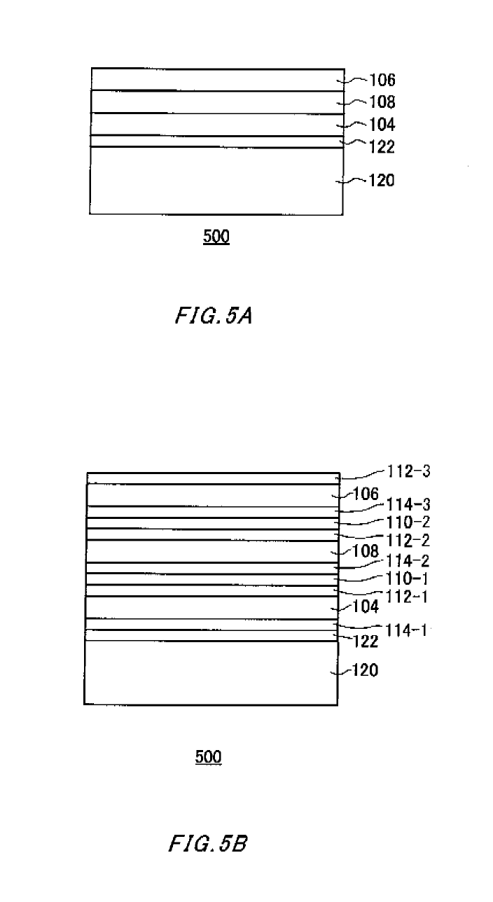

FIG. 5A illustrates the cross-section of a semiconductor wafer 500. The semiconductor wafer 500 has, on a base wafer 120, instead of the support 102 as shown in FIGS. 1 to 4, a first crystal layer 104, an intermediate crystal layer 108, and a second crystal layer 106 stacked in the stated order. The first crystal layer 104, the intermediate crystal layer 108, and the second crystal layer 106 are respectively equivalent to the first crystal layer 104, the intermediate crystal layer 108, and the second crystal layer 106 included in the photo-electric conversion device 200, the photo-electric conversion device 300, the photo-electric conversion device 400.

The base wafer 120 is made of single-crystal gallium arsenide. The semiconductor wafer 500 includes a sacrificial layer 122 between the first crystal layer 104 and the base wafer 120. The sacrificial layer 122 is lattice-matched or pseudo lattice-matched to the base wafer 120. The sacrificial layer 122 is made of an InₘAlₙGa₁₋ₘ₋ₙAS (0≦m<1, 0<n≦1, 0<n+m≦1) epitaxial crystal. Alternatively, the sacrificial layer 122 may be made of InₘAlₙGa₁₋ₘ₋ₙAs (0≦m<0.2, 0.8≦n≦1, 0.8<n+m≦1). For example, the lattice constant of the sacrificial layer 122 is between the lattice constant of the base wafer 120 and the lattice constant of the first crystal layer 104.

The semiconductor wafer 500 is suitably used for producing the photo-electric conversion device 200. When the semiconductor wafer 500 is used to produce the photo-electric conversion device 200, the sacrificial layer 122 is removed from the semiconductor wafer 500. In this way, the photo-electric conversion device 200 does not include the base wafer 120 and the sacrificial layer 122.

FIG. 5B illustrates another embodiment of the semiconductor wafer 500. The semiconductor wafer 500 may have, on the sacrificial layer 122, a first back surface field layer 114-1, a first crystal layer 104, a first window layer 112-1, a tunnel junction layer 110-1, a second back surface field layer 114-2, an intermediate crystal layer 108, a second window layer 112-2, a tunnel junction layer 110-2, a third back surface field layer 114-3, a second crystal layer 106, and a third window layer 112-3 formed in the stated order. The first bask surface field layer 114-1, the second back surface field layer 114-2, the third back surface field layer 114-3, the first window layer 112-1, the second window layer 112-2 and the third window layer 112-3 have a larger band gap than any of the First crystal layer 104, the intermediate crystal layer 108, and the second crystal layer 106, for example.

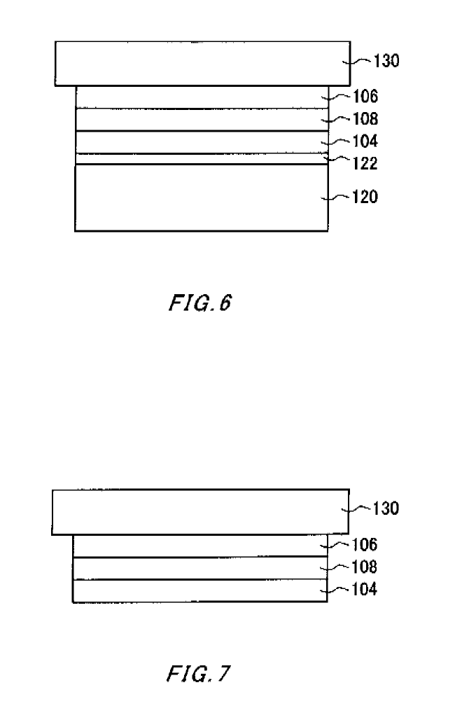

FIGS. 6 and 7 illustrate the cross-section of the semiconductor wafer 500 observed during its production process. To begin with, as shown in FIG. 6, the sacrificial layer 122, which is an InₘAlₙGa₁₋ₘ₋ₙAs (0≦m<0.2, 0.8≦n≦1, 0.8<n+m≦1) layer, is epitaxially grown on the base wafer 120, which is made of single-crystal gallium arsenide. Following this, the first crystal layer 104, which is made of SiₓGe₁₋ₓ (0≦x<1) is epitaxially grown on the sacrificial layer 122. Subsequently, the intermediate crystal layer 108, which is made of a group 3-5 compound semiconductor having a larger band gap than the first crystal layer 104, is epitaxially grown on the first crystal layer 104. In addition, the second crystal layer 106, which is made of a group 3-5 compound semiconductor having a larger band gap than the intermediate crystal layer 108, is epitaxially grown on the intermediate crystal layer 108.

The step of epitaxially growing the sacrificial layer 122 is preferably performed in a different atmosphere than the step of epitaxially growing the first crystal layer 104. The step of epitaxially growing the first crystal layer 104 is preferably performed in a different atmosphere than the step of epitaxially growing the intermediate crystal layer 108 and the step of epitaxially growing the second crystal layer 106.

For example, after the step of epitaxially growing the sacrificial layer 122 and before the step of epitaxially growing the first crystal layer 104, and after the step of epitaxially growing the first crystal layer 104 and before the step of epitaxially growing the sacrificial layer 122, the atmosphere present in the reaction chamber to epitaxially grow each layers therein is replaced with one or more gases selected from hydrogen, nitrogen and argon. Additionally or alternatively, the pressure in the reaction chamber may be reduced.

The step of epitaxially growing the first crystal layer 104 may be performed in a different reaction chamber from the step of epitaxially growing the intermediate crystal layer 108 and the step of epitaxially growing the second crystal layer 106. The gas replacement or pressure reduction in the reaction chamber and the use of different reaction chambers in the respective steps as described above clearly separates the deposition process of the SiGe-based epitaxial growth and the deposition process of the GaAs-based epitaxial growth from each other. In this manner, the impurities and the like can be prevented from mixing, thereby enabling crystalline films with good crystallinity to he formed.

By performing the above-described steps, the semiconductor wafer 500 can be formed. Between the step of epitaxially growing the sacrificial layer 122 and the step of epitaxially growing the first crystal layer 104, and between the step of epitaxially growing the first crystal layer 104 and the step of epitaxially growing the second crystal layer 106, the tunnel junction layers 110, the window layers 112 and the back surface field layers 114 are preferably formed.

Following this, a temporary support 130 is attached to the second crystal layer 106 of the semiconductor wafer 500. As shown in FIG. 7, the sacrificial layer 122 is then removed to separate the first crystal layer 104, the second crystal layer 106, and the intermediate crystal layer 108 from the base wafer 120. A support 102 is attached to the surface of the first crystal layer 104, which is exposed by separating the first crystal layer 104, the intermediate crystal layer 108 and the second crystal layer 106 from the base wafer 120. After this, the temporary support 130 is removed, so that the photo-electric conversion device 200 can be produced. If the temporary support 130 is a transparent support, a photo-electric conversion device can be obtained that receives light through the transparent support. The removed base wafer can be reused to produce another semiconductor wafer.

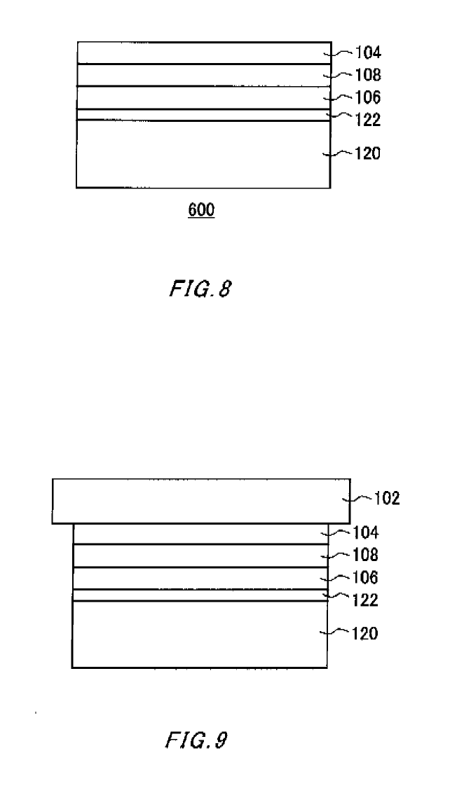

FIG. 8 illustrates the cross-section of a semiconductor wafer 600. The semiconductor wafer 600 has, on the base water 120, a sacrificial layer 122, a second crystal layer 106, an intermediate crystal layer 108, and a first crystal layer 104 stacked in the stated order. When compared with the semiconductor wafer 500 shown in FIG. 5A, the semiconductor wafer 600 is structured such that the first crystal layer 104 and the second crystal layer 106 are reversed in position. The first crystal layer 104, the intermediate crystal layer 108 and the second crystal layer 106 are epitaxial crystal layers corresponding to the semiconductor layers included in the photo-electric conversion device 200, the photo-electric conversion device 300, and the photo-electric conversion device 400.

The base wafer 120 is made of, for example, single-crystal gallium arsenide. The semiconductor wafer 600 has the sacrificial layer 122 between the second crystal layer 106 and the base wafer 120. The sacrificial layer 122 is lattice-matched or pseudo lattice-matched to the base wafer 120. The sacrificial layer 122 is, for example, made of InₘAlₙGa₁₋ₘ₋ₙAs (0≦m<1, 0<n≦1, 0<n+m≦1) epitaxial crystal. The sacrificial layer 122 may be made of InₘAlₙGa₁₋ₘ₋ₙAs (0≦m<0.2, 0.8≦n≦1, 0.8<n+m≦1). The semiconductor wafer 600 is suitably used to produce the photo-electric conversion device 200.

FIG. 9 illustrates the cross-section of the semiconductor wafer 600 observed during its production process. To start with, the sacrificial layer 122, which is made of InₘAlₙGa₁₋ₘ₋ₙAs (0≦m<0.2, 0.8≦n≦1, 0.8≦n+m≦1), is epitaxially grown on the base wafer 120, which is made of single-crystal gallium arsenide. After this, the second crystal layer 106 made of a group 3-5 compound semiconductor is epitaxially grown on the sacrificial layer 122. Subsequently, the intermediate crystal layer 108, which is made of a group 3-5 compound semiconductor having a smaller band gap than the second crystal layer 106, is epitaxially grown on the second crystal layer 106. In addition, the first crystal layer 104, which is made of SiₓGe₁₋ₓ (0≦x<1) and has a smaller band gap than the intermediate crystal layer 108, is epitaxially grown on the intermediate crystal layer 108.

Here, the step of epitaxially growing the sacrificial layer 122, the step of epitaxially growing the second crystal layer 106, and the step of epitaxially growing the intermediate crystal layer 108 are preferably performed in a different atmosphere than the step of epitaxially growing the first crystal layer 104.

For example, after the step of epitaxially growing the intermediate crystal layer 108 and before the step of epitaxially growing the first crystal layer 104, the atmosphere in the reaction chamber to epitaxially grow each layers is replaced with one or more gases selected from hydrogen, nitrogen and argon. Additionally or alternatively, the pressure in the reaction chamber may be reduced.

The step of epitaxially growing the sacrificial layer 122 may be performed in a different reaction chamber than the step of epitaxially growing the first crystal layer 104. The gas replacement or pressure reduction and the use of different reaction chambers in each steps as described above clearly separates the deposition process of the SiGe-based epitaxial growth from the deposition process of the GaAs-based epitaxial growth. In this manner, the impurities and the like can be prevented from mixing, thereby enabling crystalline films with good crystallinity to be formed.

Here, it is preferable to form the tunnel junction layers 110, the window layers 112 and the back surface field layers 114. Since each epitaxial growth steps are performed in different reaction chambers as described above, the deposition process of the SiGe-based epitaxial growth is clearly separated from the deposition process of the GaAs-based epitaxial growth. In this manner, the impurities and the like can be prevented from mixing, thereby enabling crystalline films with good crystallinity to be formed.

Furthermore, the support 102 that is made of one or more materials selected from the group consisting of metals, plastics and ceramics is attached to the epitaxial crystal layers including the first crystal layer 104, the second crystal layer 106, and the intermediate crystal layer 108 of the semiconductor wafer 600. After this, the sacrificial layer 122 is removed to separate the epitaxial crystal layers from the base wafer 120. In this way, the photo-electric conversion device 200 can be produced. The ceramics may be glass form. Alternatively, after the sacrificial layer 122 may be removed to separate the epitaxial crystal layers from the base wafer 120, a different transparent support may be attached to the second crystal layer 106. In this way, a photo-electric conversion device can also be formed.

Alternatively, a plurality of electrodes can be formed so as to be electrically coupled to the base wafer 120 and the epitaxial crystal layers without removing the base wafer 120 from the semiconductor wafer. Assuming that the base wafer 120 is made of a p-type or n-type semiconductor that has the same conductivity type as the epitaxial crystal layers that are in contact with the base wafer 120, the base wafer 120 can be used as a common electrode to increase the area efficiency of the photo-electric conversion device. The semiconductor is preferably a low-resistance semiconductor, specifically, has a resistivity of 10⁻¹ Ωcm or less.

When the support 102 made of one or more materials selected from the group consisting of metals, plastics and ceramics is attached to the base wafer 120 or the epitaxial crystal layers, an electrode that can be electrically coupled to the base wafer 120 or the epitaxial crystal layers may he formed in advance on the to-be-attached surface of the epitaxial crystal layers. When the support 102 is made of an electrically insulative material, an interconnection that can be electrically coupled to an electrode that can be electrically coupled to the base wafer 120 or the epitaxial crystal layers may be formed in advance on the to-he-attached surface of the support 102.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must he performed in this order.

What is claimed is:

1. A semiconductor wafer comprising:
a base wafer;
a sacrificial layer that is lattice-matched or pseudo lattice-matched to the base wafer;
a first crystal layer that is formed on the sacrificial layer and made of an epitaxial crystal of SiₓGe₁₋ₓ (0≦x<1); and
a second crystal layer that is formed on the first crystal layer and made of an epitaxial crystal of a group 3-5 compound semiconductor having a larger band gap than the first crystal layer.

2. The semiconductor wafer as set forth in claim 1, wherein
the base wafer is made of single-crystal GaAs.

3. The semiconductor wafer as set forth in claim 2, wherein
the sacrificial layer is made of an epitaxial crystal of InₘAlₙGa₁₋ₘ₋ₙAs (0≦m<0.2, 0.8≦n≦1, 0.8<n+m≦1).

4. The semiconductor wafer as set forth in claim 1, further comprising
an intermediate crystal layer that is formed between the first crystal layer and the second crystal layer and made of an epitaxial crystal of a group 3-5 compound semiconductor.

5. The semiconductor wafer as set forth in claim 4, wherein
the intermediate crystal layer has a larger band gap than the first crystal layer and a smaller band gap than the second crystal layer.

6. The semiconductor wafer as set forth in claim 4, further comprising
tunnel junction layers one of which is formed between the first crystal layer and the intermediate crystal layer and the other of which is formed between the intermediate crystal layer and the second crystal layer.

7. The semiconductor wafer as set forth in claim 4, wherein
the intermediate crystal layer is made of In_{y}Ga_{1-y}As_{z}P_{1-z} (0≦y<1, 0<z≦1), and
the second crystal layer is made of Al_{w}InₜGa_{1-w-t}As_{z′}P_{1-z′} (0≦w<1, 0≦t≦1, 0≦w+t<1, 0≦z′≦1).

8. The semiconductor wafer as set forth in claim 4, wherein
the intermediate crystal layer is made of GaAs, and
the second crystal layer is made of In_{0.5}Ga_{0.5}P.

9. The semiconductor wafer as set forth in claim 4, comprising
on the sacrificial layer, a first back surface field layer, the first crystal layer, a first window layer, a first tunnel junction layer, a second back surface field layer, the intermediate crystal layer, a second window layer, a second tunnel junction layer, a third back surface field layer, the second crystal layer, and a third window layer arranged in the stated order, and
the first back surface field layer, the second back surface field layer, the third back surface field layer, the first window layer, the second window layer and the third window layer have a larger band gap than any layer selected from among the first crystal layer, the intermediate crystal layer and the second crystal layer.

10. A method for producing a semiconductor wafer, the method comprising:
forming, on a base wafer, a sacrificial layer that is lattice-matched or pseudo lattice-matched to the base wafer;
epitaxially growing, on the sacrificial layer, a first crystal layer made of SiₓGe₁₋ₓ(0≦x<1);
epitaxially growing, on the first crystal layer, an intermediate crystal layer made of a group 3-5 compound semiconductor; and
epitaxially growing, on the intermediate crystal layer, a second crystal layer made of a group 3-5 compound semiconductor that has a larger band gap than the first crystal layer.

11. A method for producing a semiconductor wafer, the method comprising:
forming, on a base wafer, a sacrificial layer that is lattice-matched or pseudo lattice-matched to the base wafer;
epitaxially growing, on the sacrificial layer, a second crystal layer made of a group 3-5 compound semiconductor that has a larger band gap than the sacrificial layer;
epitaxially growing, on the second crystal layer, an intermediate crystal layer made of a group 3-5 compound semiconductor; and
epitaxially growing, on the intermediate crystal layer, a first crystal layer made of SiₓGe₁₋ₓ (0≦x<1).

12. The method as set forth in claim 10 for producing a semiconductor wafer, wherein
the base wafer is made of single-crystal GaAs.

13. The method as set forth in claim 10 for producing a semiconductor wafer, wherein
during the epitaxial growth of the sacrificial layer, an epitaxial crystal layer made of InₘAlₙGa₁₋ₘ₋ₙAs (0≦m<1, 0<n≦1, 0<n+m≦1) is epitaxially grown.

14. The method as set forth in claim 13 for producing a semiconductor wafer, wherein
during the epitaxial growth of the sacrificial layer, an epitaxial crystal layer made of InₘAlₙGa₁₋ₘ₋ₙAs (0≦m<0.2, 0.8≦n≦1, 0.8<n+m≦1) is epitaxially grown.

15. The method as set forth in claim 10 for producing a semiconductor wafer, wherein
the intermediate crystal layer has a larger band gap than the first crystal layer and a smaller band gap than the second crystal layer.

16. The method as set forth in claim 15 for producing a semiconductor wafer, wherein
a tunnel junction layer is formed between the first crystal layer and the intermediate crystal layer and another tunnel junction layer is formed between the intermediate crystal layer and the second crystal layer.

17. The method as set forth in claim 15 for producing a semiconductor wafer, wherein
the intermediate crystal layer is made of In_{y}Ga_{1-y}As_{z}P_{1-z} (0≦y<1, 0<z≦1), and
the second crystal layer is made of Al_{w}InₜGa_{1-w-t}As_{z′}P_{1-z′} (0≦w≦1, 0≦t≦1, 0≦w+t≦1, 0≦z′≦1).

18. The method as set forth in claim 15 for producing a semiconductor wafer, the method comprising:
forming, on the sacrificial layer, a first back surface field layer;
forming, on the first back surface field layer, the first crystal layer;
forming, on the first crystal layer, a first window layer;
forming, on the first window layer, a first tunnel junction layer;
forming, on the first tunnel junction layer, a second back surface field layer;
forming, on the second back surface field layer, the intermediate crystal layer;
forming, on the intermediate crystal layer, a second window layer;
forming, on the second window layer, a second tunnel junction layer;
forming, on the second tunnel junction layer, a third back surface field layer;
forming, on the third back surface field layer, the second crystal layer; and
forming, on the second crystal layer, a third window layer, wherein
the first back surface field layer, the second hack surface field layer, the third back surface field layer, the first window layer, the second window layer and the third window layer have a larger band gap than any layer selected from among the first crystal layer, the intermediate crystal layer and the second crystal layer.

19. The method as set forth in claim 10 for producing a semiconductor wafer, wherein
the epitaxial growth of the sacrificial layer is performed in a different atmosphere than the epitaxial growth of the first crystal layer, and
the epitaxial growth of the first crystal layer is performed in a different atmosphere than the epitaxial growth of the intermediate crystal layer.

20. The method as set forth in claim 19 for producing a semiconductor wafer, the method further comprising
between the epitaxial growth of the sacrificial layer and the epitaxial growth of the first crystal layer, and between the epitaxial growth of the first crystal layer and the epitaxial growth of the intermediate crystal layer, replacing the atmosphere in a reaction chamber to perform the respective epitaxial growths with one or more gases selected from hydrogen, nitrogen and argon, or reducing the pressure in the reaction chamber.

21. The method as set forth in claim 19 for producing a semiconductor wafer, wherein
the epitaxial growth of the first crystal layer is performed in a different reaction chamber than the epitaxial growth of the intermediate crystal layer and the epitaxial growth of the second crystal layer.

22. A method for producing a photo-electric conversion device, the method comprising:
providing the semiconductor wafer as set forth in claim 1;
attaching a first support onto the second crystal layer; and
removing the sacrificial layer to separate the first crystal layer from the base wafer.

23. The method as forth in claim 22 for producing a photo-electric conversion device, the method further comprising:
attaching a second support made of any material selected from among a metal, a plastic, and a ceramic onto a surface of the first crystal layer that is exposed by the separation from the base wafer; and
removing the first support.

24. The method as set forth in claim 22 for producing a photo-electric conversion device, wherein
the first support is transparent, and
the method further comprises
attaching a second support that is made of any material selected from among a metal, a plastic, and a ceramic onto a surface of the first crystal layer that is exposed by the separation from the base wafer.

25. A method for producing a photo-electric conversion device, the method comprising
providing the semiconductor wafer as set forth in claim 1, and forming a plurality of electrodes that are to be electrically coupled to the base wafer and the second crystal layer, wherein
the base wafer is made of a semiconductor having a p-type or an n-type conductivity.
